(19) United States
(12) Patent Application Publication
(10) Pub. No.: US 2026/0040774 A1
(43) Pub. Date: Feb. 5, 2026

(54) DISPLAY PANEL AND DISPLAY DEVICE

(71) Applicants: HEFEI XINSHENG OPTOELECTRONICS TECHNOLOGY CO., LTD., Hefei, Anhui (CN); BOE TECHNOLOGY GROUP CO., LTD., Beijing (CN)

(72) Inventors: Ning Liu, Beijing (CN); Bin Zhou, Beijing (CN); Leilei Cheng, Beijing (CN); Xiaoqing Xu, Beijing (CN)

(73) Assignees: HEFEI XINSHENG OPTOELECTRONICS TECHNOLOGY CO., LTD., Hefei, Anhui (CN); BOE TECHNOLOGY GROUP CO., LTD., Beijing (CN)

(21) Appl. No.: 18/996,308

(22) PCT Filed: May 21, 2024
(86) PCT No.: PCT/CN2024/094321

§ 371 Date: Jan. 17, 2025

(30) Foreign Application Priority Data
Jun. 13, 2023 (CN) 202310706226.2

(51) Int. Cl. H10K 59/124; H10K 59/121

(52) U.S. Cl. CPC H10K 59/124; H10K 59/1213

(57) ABSTRACT

This application discloses a display panel and a display device. In a specific embodiment, the display panel includes a substrate and a plurality of pixels arranged in an array on the substrate. The pixels include a light-emitting region and a transparent region. The light-emitting region includes a driving circuit layer, a planarization layer, a first electrode, a light-emitting layer, and a second electrode, which are sequentially disposed on the substrate. An edge portion of the planarization layer close to the transparent region has a first overlapping area with the first electrode in their orthographic projections on the substrate. The light-emitting region further includes a protrusion portion, whose thickness is less than that of the planarization layer. The protrusion portion is closer to the substrate than the planarization layer and covers the first overlapping area in its orthographic projection on the substrate.

### CROSS-REFERENCE TO RELATED APPLICATIONS

This application claims priority to Chinese Patent Application No. 202310706226.2, filed in China on Jun. 13, 2023, the entire contents of which are incorporated herein by reference.

### TECHNICAL FIELD

The present disclosure relates to the field of display technology, and in particular to a display panel and a display device.

### BACKGROUND

A transparent display panel is increasingly being applied in various scenarios, such as vehicle windows in cars, subways, and trains, as well as in display windows of shopping malls and supermarkets, and advertising boards. The inventors have found that in related technologies, transparent display panels often encounter defects such as dark spots caused by pixels failing to display properly, which adversely affects product yield.

### SUMMARY

The purpose of the present disclosure is to provide a display panel and a display device for solving at least one of the problems existing in the prior art.

To achieve the above objectives, the present disclosure proposes the following technical solutions:
the first aspect of the present disclosure provides a display panel, comprising a substrate and a plurality of pixels arranged in an array on the substrate, the pixels comprising a light-emitting region and a transparent region, the light-emitting region comprising, in sequence on the substrate, a driving circuit layer, a planarization layer, a first electrode, a light-emitting layer, and a second electrode; an edge portion of the planarization layer adjacent to the transparent region has a first overlapping area with the orthographic projection of the first electrode on the substrate, the light-emitting region further comprises a raised portion, the thickness of the raised portion is smaller than the thickness of the planarization layer, and the raised portion is closer to the substrate compared with the planarization layer and covers the first overlapping area in its orthographic projection on the substrate.

Optionally, the light-emitting region further comprises multiple signal lines electrically connected to the pixel; the signal lines forming the protrusion.

Optionally, the light-emitting region further comprises an auxiliary electrode electrically connected to the second electrode; the signal line comprises an auxiliary electrode wiring electrically connected to the auxiliary electrode; the auxiliary electrode wiring is provided with an extension portion, and the extension portion forms the protruded portion.

Optionally, the protrusion comprises a first part, the orthographic projection of the first part on the substrate coinciding with the orthographic projection of the first overlapping region on the substrate; in the direction from the light-emitting area to the transparent area, the length of the first part is 5 μm-20 μm.

Optionally, the protrusion further comprises a second part; the orthogonal projection of the second part on the substrate is located on the side of the first overlapping region close to the transparent area.

Optionally, the first electrode comprises a first step portion and a second step portion; the orthographic projection of the first step portion on the substrate covers the intersection of the orthographic projections of the first part and the second part on the substrate; the orthographic projection of the second step portion on the substrate covers the edge of the second part close to the transparent region in the orthographic projection on the substrate.

Optionally, in the direction of the light-emitting region pointing to the transparent region, the length of the second part is equal to the length of the first part.

Optionally, the thickness ratio of the protrusion to the planarization layer comprises 1:3-1:5.

Optionally, the driving circuit layer comprises an active layer, a gate insulating layer, gates of the thin-film transistors, a dielectric layer, and a source-drain metal layer stacked sequentially; the source-drain metal layer forms the source and drain of the thin-film transistors; the light-emitting region further comprises a passivation layer disposed between the driving circuit layer and the planarization layer, and the anode is connected to the source or drain through a via in the passivation layer.

Optionally, the auxiliary electrode wiring is arranged in the same layer as the source/drain metal layer.

The second aspect of the present disclosure provides a display device, comprising the display panel provided in the first aspect of the present disclosure.

The beneficial effects of the present disclosure are as follows:
the technical solution described in this disclosure, by forming a protrusion at the edge of the planarization layer close to the substrate side, reduces the inclination angle at the edge of the planarization layer; this makes the slope at the edge of the planarization layer more gradual, thereby reducing the climbing difficulty of the first electrode, effectively lowering the risk of fractures and defects in the first electrode, thus reducing the risk of dark spot defects on the display panel and improving product yield.

### BRIEF DESCRIPTION OF THE DRAWINGS

The specific embodiments of the present disclosure are further described in detail below with reference to the accompanying drawings.

FIG. 1 shows a schematic diagram of pixels in a display panel in the related art;

FIG. 2 shows a cross-sectional schematic diagram of pixels in a display panel in the related art;

FIG. 3 shows a schematic diagram of microscopic observation of the edge region of a planarization layer as shown in FIG. 1;

FIG. 4 shows a cross-sectional schematic diagram of SEM (scanning electron microscopy) observation of the edge region of the planarization layer as shown in FIG. 1;

FIG. 5 shows a schematic diagram of pixels in a display panel provided by an embodiment of the present disclosure;

FIG. 6 shows a cross-sectional schematic diagram of pixels in a display panel provided by an embodiment of the present disclosure;

FIG. 7 shows a simplified schematic diagram of the edge region of a planarization layer in the related art;

FIG. 8 shows a simplified schematic diagram of the edge region of a planarization layer in an embodiment of the present disclosure.

### DETAILED DESCRIPTION

The terms “on . . . ”, “forming on . . . ”, and “disposed on . . . ” described in this disclosure can represent a layer directly forming or disposed on another layer; they can also represent a layer indirectly forming or disposed on another layer, i.e., other layers exist between the two layers.

It should be noted that while the terms “first,” “second,” etc., can be used herein to describe various components, elements, regions, layers, and/or portions, these components, elements, regions, layers, and/or portions should not be limited by these terms; rather, these terms are used to distinguish one component, element, region, layer, and/or portion from another. Thus, for example, a first component, first element, first region, first layer, and/or first part discussed below can be referred to as a second component, second element, second region, second layer, and/or second part without departing from the teachings of the present disclosure.

In the present disclosure, unless otherwise specified, the term “same-layer setting” refers to two layers, components, structures, elements, or parts being capable of being formed through the same preparation process (e.g., patterning process, etc.); furthermore, these two layers, components, structures, elements, or parts are generally formed from the same material. For example, the same-layer setting of two or more functional layers refers to these functional layers, which are in the same-layer setting, being capable of being formed by adopting the same material layer and utilizing the same preparation process, thereby simplifying the preparation process of the display substrate.

In the present disclosure, unless otherwise stated, the term “patterning process” generally comprises steps such as photoresist coating, exposing, developing, etching, and photoresist stripping. The term “single patterning process” refers to the process of forming a patterned layer, component, or element using one mask.

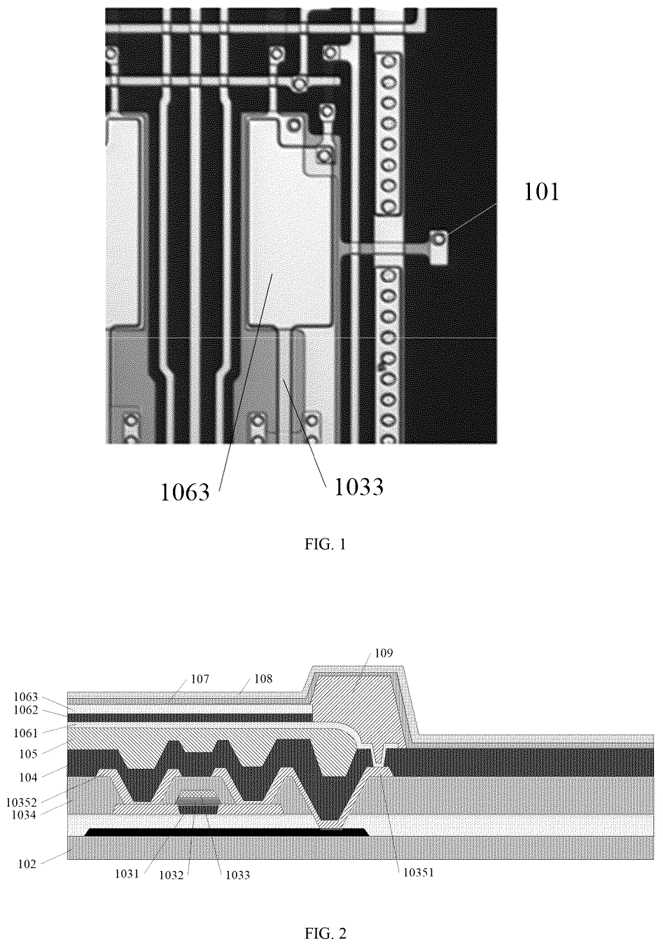

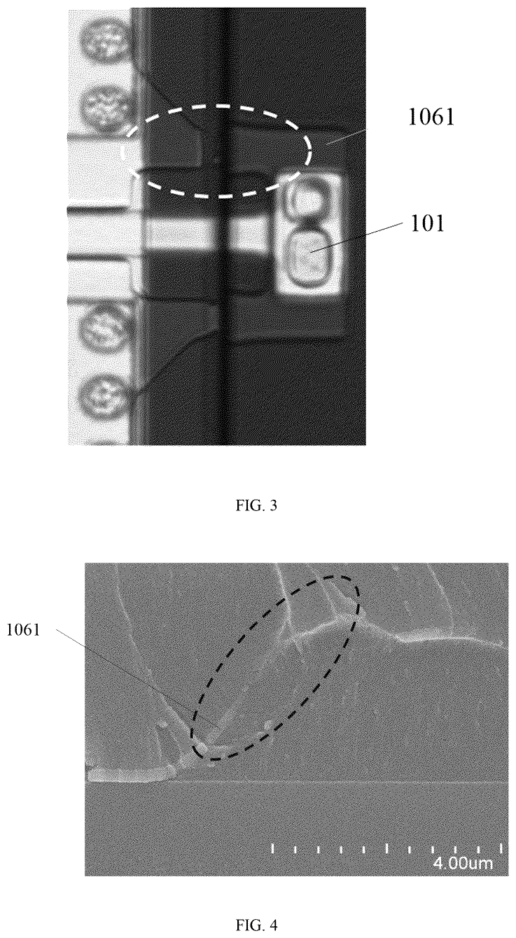

The inventors discovered that in the relevant technology, transparent display panels often exhibit dark spot defects caused by the inability of pixels to display properly, which affects product yield. To determine the cause of the dark spot defects in transparent display panels, the inventors conducted research on the structure of transparent display panels. Taking Organic Light-Emitting Diode (OLED) transparent display panels as an example, as shown in FIG. 1 and FIG. 2, the display area of the OLED transparent display panel comprises a substrate and multiple pixels arranged in an array on the substrate. Each pixel comprises a light-emitting region and a transparent region, as shown in FIG. 1, where the left side of the passivation layer (PVX) via 101 for the anode (Anode) connecting to the source (Source) of the thin-film transistor (TFT) is the light-emitting region, and the right side of the passivation layer via 101 is the transparent region. As shown in FIG. 1 and FIG. 2, the light-emitting region comprises, sequentially on the substrate 102, a driving circuit layer, a passivation layer (PVX) 104, a planarization layer (PLN) 105, an anode, a light-emitting layer 107, and a cathode 108. The driving circuit layer comprises sequentially stacked layers: an active layer (Active) 1031, a gate insulating layer (GI) 1032, a gate (Gate) 1033 of the thin-film transistor, an interlayer dielectric layer (ILD) 1034, and a source/drain (SD) metal layer. The source/drain metal layer forms the source (Source) 10351 and drain (Drain) 10352 of the thin-film transistor. The anode, as an example, is a composite structure comprising sequentially stacked layers, such as a first thin-film electrode 1061 made of indium tin oxide (ITO), a metal electrode 1062 serving as a reflective electrode, and a second thin-film electrode 1063 made of indium tin oxide (ITO). The first thin-film electrode 1061 connects to the source 10351 through the passivation layer 104 via 101. Furthermore, as shown in FIG. 2, the light-emitting region also comprises a pixel defining layer (PDL) 109 for defining the area of the light-emitting region. As shown in FIG. 1 and FIG. 2, to improve the light transmittance of the transparent region, no planarization layer is provided in the transparent region of the OLED transparent display panel. Therefore, the planarization layer 105 in the light-emitting region forms a highly inclined planarization layer edge close to the boundary of the light-emitting region. In this case, when forming the first thin-film electrode 1061 after the planarization layer 105, the first thin-film electrode 1061 has to climb a steep slope at the planarization layer edge. Due to the steep slope, the first thin-film electrode 1061 is prone to breaking. The morphology of the planarization layer edge region where the fracture of the first thin-film electrode 1061 tends to occur is illustrated in FIG. 3 and FIG. 4; the dashed box in FIG. 4 corresponds to the dashed box in FIG. 3. The fracture of the first thin-film electrode 1061 causes the anode to fail in receiving the data signal, leading to an inability of the light-emitting region of the pixel to display properly, which results in dark spot defects.

In view of this, the embodiments of the present disclosure provide a display panel, comprising a substrate and a plurality of pixels arranged in an array on the substrate; the pixels comprise a light-emitting region and a transparent region, the light-emitting region comprises, sequentially disposed on the substrate, a driving circuit layer, a planarization layer, a first electrode, a light-emitting layer, and a second electrode; an edge portion of the planarization layer close to the transparent region has a first overlapping area with a orthographic projection of the first electrode on the substrate, the light-emitting region further comprises a protrusion, the thickness of the protrusion is less than the thickness of the planarization layer, and the protrusion is closer to the substrate compared to the planarization layer; the orthographic projection of the protrusion on the substrate overlaps the first overlapping area.

The display panel provided by the embodiments of the present disclosure comprises a protrusion formed on the edge of the planarization layer close to the substrate side; this reduces the inclination angle at the edge of the planarization layer, making the slope at the edge position smoother. As a result, the climbing difficulty of the first electrode is reduced, effectively decreasing the risk of breakage defects in the first electrode; this further reduces the risk of dark spot defects in the display panel, thereby improving the product yield.

Since the pixels comprise transparent areas, the display panel provided in the embodiments of this disclosure is a transparent display panel; in addition, the display panel provided by this disclosure can be an Organic Light-Emitting Diode (OLED) display panel or a Light Emitting Diode (LED) display panel, etc. Below, the display panel provided by this disclosure is described using an OLED display panel, namely, an OLED transparent display panel is described below.

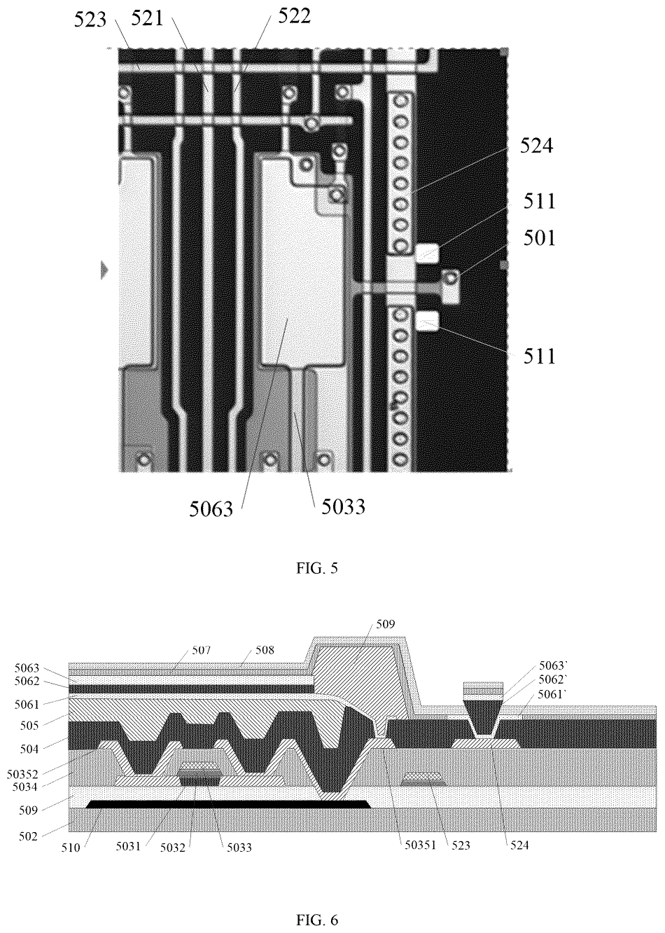

The OLED transparent display panel provided by the embodiments of this disclosure comprises a substrate and multiple pixels arranged in an array on the substrate. Each pixel comprises a light-emitting area and a transparent area; for example, as shown in FIG. 5, the left side of the passivation layer (PVX) via 501 for the anode (Anode) connecting to the source (Source) of the thin-film transistor (TFT) is the light-emitting area, and the right side of the passivation layer via 501 is the transparent area. As shown in FIG. 5 and FIG. 6, the light-emitting area comprises a driving circuit layer successively arranged on the substrate 502, a passivation layer (PVX) 504, a planarization layer (PLN) 505, an anode, a light-emitting layer 507, and a cathode 508.

As shown in FIG. 5 and FIG. 6, in the OLED transparent display panel provided by the embodiments of the present disclosure:
the substrate 502 can comprise materials such as glass or quartz; the OLED transparent display panel can further comprise a barrier layer (Barrier) (not shown in the figure) and a buffer layer (Buffer) 509 located between the substrate 502 and the driving circuit layer. For example, the barrier layer and the buffer layer 509 can be formed entirely on the substrate 502. For instance: the barrier layer can adopt inorganic insulating materials such as silicon oxide, silicon nitride, or silicon oxynitride; the buffer layer 509 can also adopt inorganic insulating materials such as silicon oxide, silicon nitride, or silicon oxynitride. The barrier layer is conducive to blocking water and oxygen from entering the subsequently formed OLED from the bottom; the buffer layer 509 contributes to the quality of subsequent material deposition.

The drive circuit layer can also be referred to as the thin-film transistor (TFT) layer. The drive circuit layer comprises an active layer (Active) 5031, a gate insulating layer (GI) 5032, the gate (Gate) 5033 of the thin-film transistor, a dielectric layer (ILD) 5034, and a source-drain metal layer (SD) arranged sequentially. The source-drain metal layer forms the source (Source) 50351 and the drain (Drain) 50352 of the thin-film transistor. Specifically, the drive circuit layer comprises the active layer 5031 formed on the buffer layer 509 using a patterning process; the gate insulating layer 5032 formed on the active layer 5031 through deposition or other methods; the gate 5033 of the thin-film transistor formed on the gate insulating layer 5032 using a patterning process; the dielectric layer 5034 formed on the gate 5033 through deposition or other methods; and the source-drain metal layer formed on the dielectric layer 5034. The source-drain metal layer forms the source 50351 and the drain 50352 of the thin-film transistor. The active layer 5031 can, for instance, comprise a semiconductor portion and conductive portions located on two sides of the semiconductor portion and in contact with it. For example, the source 50351 is electrically connected to one conductive portion of the active layer 5031 through a via in the dielectric layer, and the drain 50352 is electrically connected to another conductive portion of the active layer 5031 through a via in the dielectric layer. For instance, the luminous region also comprises multiple signal lines. The signal lines, for example, comprise detection lines 521, data lines 522, and gate lines 523. The data lines 522 are electrically connected to the drain 50352, and the gate lines 523 are electrically connected to the gate 5033. For example, the active layer 5031 can comprise materials such as polysilicon or metal oxides. The gate insulating layer 5032 can comprise inorganic insulating materials such as silicon oxide, silicon nitride, or silicon oxynitride. The dielectric layer 5034 can comprise inorganic insulating materials such as silicon oxide, silicon nitride, or silicon oxynitride. The gate 5033 materials comprise metals or alloy materials such as aluminum, titanium, or cobalt.

Additionally, as shown in FIG. 6, the OLED transparent display panel may also comprise a light-shielding layer (LS) 510, which is positioned on the substrate 502 and projects orthogonally over the TFT structure.

The passivation layer 504 covers the source/drain metal layer and the exposed dielectric layer 5034; the planarization layer 505 covers the passivation layer 504. The anode, for example, is a composite structure comprising a first thin-film electrode 5061 made of indium tin oxide (ITO), a metal electrode 5062 serving as a reflective electrode, and a second thin-film electrode 5063 made of indium tin oxide (ITO), stacked sequentially. The first thin-film electrode 5061 is connected to the source electrode 50351 through the via of the passivation layer 501. Furthermore, as shown in FIG. 6, the light-emitting region also comprises a pixel defining layer (PDL) 509 for defining the light-emitting region area. The cathode 508 is made, for instance, of indium zinc oxide (IZO).

The OLED transparent display panel may further comprise an encapsulation layer (TFE) located on the cathode 508. For example, the encapsulation layer comprises a first inorganic encapsulation layer, an organic encapsulation layer, and a second inorganic encapsulation layer. For instance, the first inorganic encapsulation layer and the second inorganic encapsulation layer are formed using deposition or similar methods; the organic encapsulation layer is formed using an inkjet printing method. For example, the first inorganic encapsulation layer and the second inorganic encapsulation layer can be formed using inorganic materials such as silicon nitride, silicon oxide, and silicon oxynitride; the organic encapsulation layer can be formed using organic materials such as polyimide (PI) and epoxy resin. As a result, the first inorganic encapsulation layer, the organic encapsulation layer, and the second inorganic encapsulation layer together form a composite encapsulation layer, which can provide multiple layers of protection to the functional structure of the display panel and achieve better encapsulation performance.

As shown in FIG. 6, the buffer layer 509, dielectric layer 5034, light-emitting layer 507, and cathode 508 in the light-emitting region extend to the transparent area; wherein, the light-emitting layer 507 extending to the transparent area forms a disconnection at the edge of the light-emitting region, which will be specifically explained later. To improve the transmittance of the transparent area, for example, the planarization layer 505, which is made of a resin material with a relatively thick thickness, does not extend to the transparent area; in other words, the transparent area does not comprise the planarization layer. As shown in FIG. 5 and FIG. 6, the edge of the planarization layer 505 is located close to the edge of the light-emitting region; the edge part of the planarization layer 505 close to the transparent area has a first overlapping region on the substrate 502, which overlaps with the first thin-film electrode 5061 in its orthographic projection on the substrate 502. In the OLED transparent display panel provided by the embodiments of the present disclosure, the light-emitting region of the pixel further comprises a protrusion 511. The thickness of the protrusion 511 is smaller than that of the planarization layer 505; the protrusion 511 is closer to the substrate 502 compared to the planarization layer 505, and the orthographic projection of the protrusion 511 on the substrate 502 covers the first overlapping region. Herein, the thickness of the protrusion 511 refers to its length in the light-emission direction (i.e., the direction perpendicular to the substrate 502, which is the vertical direction in FIG. 6); the thickness of the planarization layer 505 is defined similarly. In addition, it can be understood that the thickness of the planarization layer 505 refers to its main-body thickness in the light-emitting region and should not be regarded as the thickness in the sloped edge region.

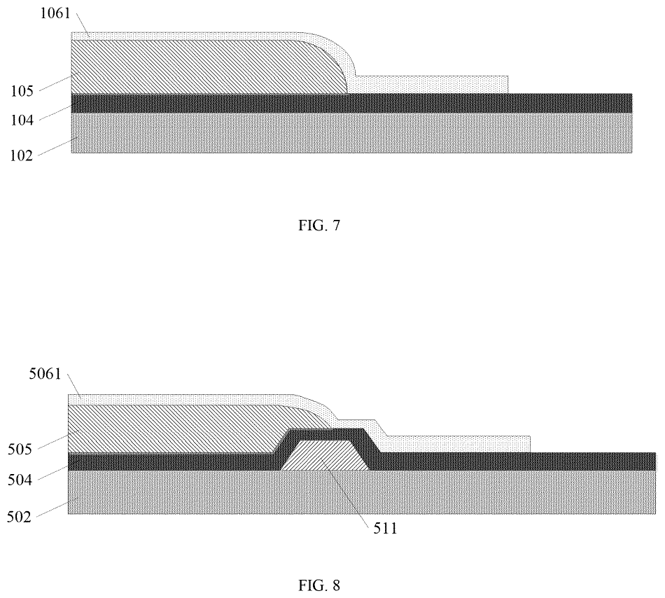

Thus, by arranging the protrusion 511 below (or on the pad) the designed position close to the edge of the transparent area of the planarization layer 505, when forming the planarization layer 505 in subsequent processes, the planarization layer material, such as resin, which is flowable, forms a planarization layer 505 with a relatively gentle edge slope; as shown in FIG. 7 and FIG. 8, by setting the protrusion 511, this embodiment of the present disclosure can transform the edge of the planarization layer 105, which is a steep slope in the related art shown in FIG. 7, into two gentler slopes formed at the edge position of the planarization layer 505 as shown in FIG. 8. As illustrated in FIG. 8, these two gentler slopes are respectively formed by the edge of the planarization layer 505 and the edge of the passivation layer 504, thereby enabling a gentler slope at the edge position of the planarization layer, reducing the climbing difficulty of the first thin film electrode 5061, effectively reducing the risk of fracture defects in the first thin film electrode 5061, thereby lowering the risk of dark spot defects in OLED transparent display panels and enhancing product yield.

In some embodiments of the present disclosure, as required, other necessary functional film layers can also be formed in the display area of the OLED transparent display panel: for example, forming storage capacitors in the light-emitting area of the pixels, which will not be elaborated here.

In one possible implementation, in the OLED transparent display panel provided by the embodiments of this disclosure, the light-emitting region further comprises multiple signal lines electrically connected to the pixels; the signal lines form a protrusion 511.

Therefore, by designing the wiring shape of the signal line to form a protrusion 511; it avoids the increase in preparation process and production cost caused by setting the protrusion 511, and effectively achieves the smoothing of the edge position of the planarization layer, reducing the climbing difficulty of the first thin film electrode 5061.

In a possible implementation, as shown in FIG. 5 and FIG. 6, the OLED transparent display panel provided by the embodiments of the present disclosure further comprises a light-emitting area comprising an auxiliary cathode electrically connected to the cathode 508; the signal line comprises an auxiliary cathode trace 524 electrically connected to the auxiliary cathode, wherein the auxiliary cathode trace 524 is provided with an extension portion, and the extension portion forms a protrusion 511.

As shown in FIG. 5 and FIG. 6, the position of the auxiliary electrode wiring 524 is relatively closer to the edge of the planarization layer 505 close to the transparent area. Therefore, for the design of the auxiliary cathode wiring 524 below the first overlapping area, an extension part is formed through the extension part, forming the protrusion 511; this can further avoid the increase in preparation process and production cost brought by setting the protrusion 511, and can effectively achieve the smoothing of the edge position of the planarization layer, reducing the slope climbing difficulty of the first thin-film electrode 5061.

In a specific example, as shown in FIG. 6, the auxiliary cathode is sequentially laminated with a first thin-film electrode layer 5061′, a metal electrode layer 5062′, and a second thin-film electrode layer 5063′; wherein the surface of the metal electrode layer 5062′ on the side close to the transparent area and the surface on the side away from the transparent area (i.e., the left and right surfaces in FIG. 6) are recessed inwardly, forming an I-shaped structure of the auxiliary cathode as shown in FIG. 6. This structure can be realized through processes such as side etching; consequently, the light-emitting layer 507 on the top of the auxiliary cathode is disconnected from the light-emitting layer 507 in the light-emitting area and extending to the transparent area. Moreover, the cathode 508 on the top of the auxiliary cathode is also disconnected from the cathode 508 in the light-emitting area and extending to the transparent area. However, the cathode 508 in the light-emitting area can be electrically connected to the metal electrode layer 5062′ of the auxiliary cathode, thereby achieving electrical connection between the auxiliary cathode and the cathode 508 in the light-emitting area. It can be understood that FIG. 6 is merely a schematic of the cross-sectional morphology. In practice, in the direction from the light-emitting area to the transparent area (i.e., the horizontal direction in FIG. 5-7), the auxiliary cathode and the auxiliary cathode wiring 512 are positioned between the sloped edge of the planarization layer 505 close to the transparent area and the passivation layer via 501 for connecting the source electrode 50351 of the thin-film transistor to the first thin-film electrode 5061; for example, refer to FIG. 5.

In a possible implementation, as shown in FIG. 6, the OLED transparent display panel provided in embodiments of the present disclosure comprises auxiliary cathode wiring 524 being arranged on the same layer as the source/drain metal layer forming the source electrode 50351 and the drain electrode 50352 of the thin-film transistor.

Thus, when performing the patterning and structuring of the source-drain metal layer, designing an extension for the auxiliary cathode wiring 524 under the first overlapping region further simplifies the fabrication process.

In a possible implementation, as shown in FIG. 8, in the OLED transparent display panel provided by the embodiments of the present disclosure, the protrusion 511 comprises a first part; the orthographic projection of the first part on the substrate 502 coincides with the orthographic projection of the first overlap area on the substrate 502, and in the direction from the light-emitting area to the transparent area, the length of the first part is 5 μm-20 μm.

Among them, the first part of the protrusion 511, namely the portion of the protrusion 511 overlapping with the orthogonal projection of the VSS planarization layer 505 on the substrate 502 as shown in FIG. 8; the above design can effectively achieve the smoothing of the edge position of the planarization layer, reducing the climbing difficulty of the first thin film electrode 5061.

In one possible implementation, in the OLED transparent display panel provided by the embodiments of the present disclosure, the protrusion 511 further comprises a second part; the orthogonal projection of the second part on the substrate 502 is located on the side of the first overlapping area closer to the transparent region.

The second part of the protrusion 511, i.e., for example as shown in FIG. 8, the right side portion of the part of the protrusion 511 that overlaps with the orthographic projection of the VSS planar layer 505 on the substrate 502; the above design can effectively achieve the smoothing of the edge position of the planar layer, reducing the climbing difficulty of the first thin-film electrode 5061.

In a possible implementation, in the OLED transparent display panel provided by the embodiments of this disclosure, in the direction from the light-emitting region to the transparent region, the length of the second part is equal to the length of the first part.

Thus, the edge position of the planar layer can be effectively smoothed, reducing the climbing difficulty of the first thin film electrode 5061. It should be noted that the equal lengths in this implementation allow for process tolerances; for instance, in the embodiments of this disclosure, a length deviation within 5% is considered equal.

In one possible implementation, the OLED transparent display panel provided in this embodiment of the present disclosure comprises a first thin-film electrode 5061, which comprises a first step portion and a second step portion; the orthographic projection of the first step portion on the substrate 502 covers the junction between the first part and the second part in the orthographic projection on the substrate 502, and the orthographic projection of the second step portion on the substrate 502 covers the edge of the second part close to the transparent region in the orthographic projection on the substrate 502.

As shown in FIG. 8, two gently sloped ramps are formed at the edge positions of the planarization layer 505; these two gently sloped ramps are respectively formed by the edge of the planarization layer 505 and the edge of the passivation layer 504. At the positions of these two gently sloped ramps at the edge of the planarization layer 505, the first thin film electrode 5061 respectively forms a relatively smooth step portion. Compared with the related technology shown in FIG. 7, the first thin film electrode 5061 significantly reduces the climbing difficulty at the edge of the planarization layer 505, thereby effectively reducing the risk of fracture defects in the first thin film electrode 5061.

In one possible implementation, the thickness ratio of the protrusion 511 to the planarization layer 505 is 1:3-1:5.

For example, the thickness of the planar layer 505 is 20000 Å; the thickness of the protrusion 511 is 5000 Å; the thickness ratio of the protrusion 511 to the planar layer 505 is 1:4.

Thus, by designing the thickness of the protrusion 511, the edge position of the planarization layer can be effectively smoothened; reducing the climbing difficulty of the first thin film electrode 5061.

Another embodiment of the present disclosure provides a display device, comprising the above-mentioned display panel. Herein, the display device can be a vehicle window display screen for transportation tools such as automobiles, subways, trains; a display screen for exhibition windows in shopping malls, supermarkets; an advertisement display screen or other products or components possessing display functions, and this embodiment does not impose limitations on this.

Evidently, the above-described embodiments of the present disclosure are merely examples provided to clearly illustrate the present disclosure and are not limitations on the implementations of the present disclosure; for those of ordinary skill in the art, other variations or modifications in different forms can be made based on the above description. It is impossible to exhaust all implementations here; any obvious variations or modifications derived from the technical solutions of the present disclosure still fall within the protection scope of the present disclosure.

1. A display panel, comprising a substrate and a plurality of pixels arranged in an array on the substrate, the pixels comprises a light-emitting region and a transparent region, the light-emitting region comprises a driving circuit layer, a planarization layer, a first electrode, a light-emitting layer, and a second electrode sequentially disposed on the substrate; an orthographic projection of the edge portion of the planarization layer close to the transparent region on the substrate forms a first overlapping area with the orthographic projection of the first electrode on the substrate; the light-emitting region further comprises a protrusion, the thickness of the protrusion is less than the thickness of the planarization layer, and the protrusion is closer to the substrate compared to the planarization layer, wherein the orthographic projection of the protrusion on the substrate covers the first overlapping area.

2. The display panel according to claim 1, wherein the light-emitting region further comprises multiple signal lines electrically connected to the pixels; the signal lines form the protrusion.

3. The display panel according to claim 2, wherein the light-emitting region further comprises an auxiliary electrode electrically connected to the second electrode; the signal line comprises an auxiliary electrode wiring electrically connected to the auxiliary electrode; the auxiliary electrode wiring is provided with an extension portion, and the extension portion forms the protrusion.

4. The display panel according to claim 1, wherein the protrusion comprises a first part, an orthographic projection of the first part on the substrate coincides with the orthographic projection of the first overlapping area on the substrate; and in a direction from the light-emitting area toward the transparent area, the length of the first part is 5 μm-20 μm.

5. The display panel according to claim 4, wherein the protrusion further comprises a second part, and the orthographic projection of the second part on the substrate is located at a side of the first overlapping area close to the transparent area.

6. The display panel according to claim 5, wherein the first electrode comprises a first step portion and a second step portion; the orthographic projection of the first step portion on the substrate covers the junction of the orthographic projection of the first part and the orthographic projection of the second part on the substrate; the orthographic projection of the second step portion on the substrate covers the orthographic projection of the edge of the second part close to the transparent area on the substrate.

7. The display panel according to claim 5, wherein in the direction of the light-emitting area toward the transparent area, the length of the second part is equal to the length of the first part.

8. The display panel according to claim 1, wherein a thickness ratio of the protrusion to the planarization layer is 1:3-1:5.

9. The display panel according to claim 3, wherein the driving circuit layer comprises an active layer, a gate insulating layer, the gate of a thin film transistor, a dielectric layer, and a source-drain metal layer stacked sequentially; the source-drain metal layer forms the source and drain of the thin film transistor; the light-emitting region further comprises a passivation layer disposed between the driving circuit layer and the planarization layer; the anode being connected to the source or the drain through a via in the passivation layer.

10. The display panel according to claim 9, wherein the auxiliary electrode wiring is arranged in the same layer as the source-drain metal layer.

11. A display device, comprising a display panel according to claim 1.
